(19) United States
(12) Patent Application Publication
(10) Pub. No.: US 2025/0124191 A1
(43) Pub. Date: Apr. 17, 2025

(54) METHOD FOR CARRYING OUT A SIMULATION ON A REAL PROCESSOR

(71) Applicant: dSPACE GmbH, Paderborn (DE)

(72) Inventor: Tobias SIELHORST, Paderborn (DE)

(73) Assignee: dSPACE GmbH, Paderborn (DE)

(21) Appl. No.: 18/914,097

(22) Filed: Oct. 12, 2024

(30) Foreign Application Priority Data
Oct. 12, 2023 (DE) 10 2023 127 837.1

(51) Int. Cl. G06F 30/20

(52) U.S. Cl. CPC G06F 30/20

(57) ABSTRACT

A method is provided for carrying out a simulation on a real processor of a first processor type, the simulation including at least one simulation model which is compiled for the first processor type. The simulation model is compiled for the first processor type on the real processor of the first processor type as an emulation of the processor of the first processor type. This provides a possibility for achieving a great flexibility in selecting the models as well as in selecting the target platform of the simulation.

This nonprovisional application claims priority under 35 U.S.C. § 119 (a) to German Patent Application No. 10 2023 127 837.1, which was filed in Germany on Oct. 12, 2023, and which is herein incorporated by reference.

### BACKGROUND OF THE INVENTION

### Field of the Invention

The invention relates to a method for carrying out a simulation on a real processor of a first processor type, the simulation including at least one simulation model, which is compiled for the first processor type.

### Description of the Background Art

A virtual control unit, a so-called V-ECU, is a piece of software which simulates a real control unit or a part of a real control unit in a simulation scenario. Different V-ECU versions cover a wide range of variants, from very simple versions to a complete version containing all components of a real control unit. In a simplified modeling, a V-ECU contains, for example, only a single application software component, and the different underlying layers of the operating system and the driver are abstracted. In a more complex version, the V-ECU contains multiple linked software components, for example the complete functionality of a control unit. In the automotive sector, for example, the AUTOSAR Runtime Environment (RTE) and the operating system are also part thereof for realistic task scheduling. If necessary, selected software components may be added to simulate the bus communication or the NVRAM. A V-ECU becomes even more realistic if the real basic software code is added, which is also used in the series code. This means that a V-ECU contains components of application and basic software and therefore provides functionalities which are comparable to those of real control units. They are used, for example, for validation during a computer-based simulation.

Since one does not work with real control unit hardware when using a V-ECU, the simulation may take place faster than in real time, so that the analysis of the simulated control unit may occur extremely time-efficiently and comfortably. Software functions, V-ECUs, or complete V-ECU networks may be simulated and tested in computer-based simulations, using software-in-the-loop tests (SIL tests).

The software development process for classic automobile applications, such as drive train or brake systems, including e-drive applications and functions for autonomous driving, may be significantly accelerated by virtual testing and validation using SIL tests. A DUT (device under test) may thus be comfortably simulated on a computer, it may be connected to physically based models, and test scripts may be easily reused on hardware-in-the-loop (HIL) systems at a later time.

Complex simulation systems are generally created for SIL tests. The models for a simulation system of this type may be present compiled in binary format or in the form of code to be compiled. The software may be present in both variants, particularly in the area of software validation. In the first case, the models are specific to the processor and operating system. In the second case, the models are generally more flexible in this regard, but this type of provision is not always available for different reasons. Arbitrary processor code may be emulated on an emulator if a corresponding processor model is present. However, the emulation is significantly slower than a native execution of commands on the target processor. If the binary code is compiled for the processor, the software may be executed on a virtual machine. If the binary code is compiled for the processor and the operating system of the simulator, it may be executed directly on the computer without virtualization.

### SUMMARY OF THE INVENTION

It is therefore an object of the invention to provide a possibility for achieving great flexibility in selecting the models as well as in selecting the target platform of the simulation.

According to an example of the invention, a method is thus provided for carrying out a simulation on a real processor of a first processor type, the simulation including at least one simulation model which is compiled for the first processor type, and whereby the simulation model compiled for the first processor type on the real processor of the first processor type is executed as an emulation of the processor of the first processor type.

An aspect of the invention is therefore that the simulation first provides a processor emulation for all models, in particular, also for a simulation model that is compiled for the processor type of the real processor. This does not correspond to the conventional procedure, since, in an SIL simulation, for example, code is normally compiled in keeping with the SIL simulator. However, the invention knowingly takes into account the fact that the method described above makes the SIL simulator slightly more complex. The advantage according to the invention then lies in a very great flexibility in selecting the models as well as in selecting the target platform of the simulation. A user of the method according to the invention may thus choose, for example, a certain target architecture of the simulator in a cloud application if it best meets his/her requirements, without having to take into account any compatibilities. The at least initial execution of the models in an emulation ensures that the simulation may be carried out correctly, even if it is not optimal for the execution speed.

Thus, it is now provided that the simulation includes at least one simulation model, which is compiled for a second processor type, which is different from the first processor type, and includes the step of executing the simulation model compiled for the second processor type on the real processor of the first processor type as an emulation of the processor of the second processor type.

This example of the invention takes into account the situation that the simulation may include at least one simulation model compiled for a second processor type, which is different from the first processor type, and, in this case, an emulation of a processor of the second processor type must take place on the real processor in order to facilitate an execution of the simulation module compiled for the second processor type on the real processor. While in this case the execution of the simulation model absolutely requires an emulation on the real processor of a processor of the processor type for which the simulation model is compiled, this would not be the case in the situation depicted at the outset. In that case, the simulation includes a simulation model which is compiled for the first processor type, so that no emulation would actually be necessary. In other words, this means that, according to the invention, an emulation of the corresponding processor type always takes place on the real processor, at least initially, regardless of the processor type for which a simulation model is compiled, even if the emulated processor type matches the processor type of the real processor. To make the method particularly efficient, preferably no check whatsoever takes place, at least initially, as to whether the processor type for which the simulation model is compiled matches the processor type of the real processor.

If, in the present case, an at least initial execution of the model in an emulation is mentioned, and if, in the present case, an emulation of the corresponding processor type takes place on the real processor, at least initially, even if the emulated processor type matches the processor type of the real processor, and absolutely no check is preferably made, at least initially, as to whether the processor type for which the simulation model is compiled matches the processor type of the real processor, this means that this applies at the beginning of the method, i.e., at least for a first simulation run. As described farther below, it is, however, sometimes possible to dispense with the emulation in question in subsequent simulation runs.

Under this aspect, it is provided that, after executing the simulation model compiled for the first processor type on the processor of the first processor type as the emulation thereof, the following steps can be carried out: executing those simulation models of the simulation on a virtual machine of the real processor which are compiled for the processor type of the real processor but not for the operating system of the real processor; and executing those simulation models of the simulation on the real processor without emulation which are compiled for the processor type of the real processor and for the operating system of the real processor.

This example of the invention thus makes better use of the existing hardware without having the modify the simulation system. As a result, two applications may be easily used thereby, namely a scalable use of general hardware and an efficient utilization of special hardware. In particular, the same simulation may run as usual outside of cloud applications as a compiled file directly on a computer and thereby meet debugging requirements without additional obstacles.

To be able to now switch to a method of this type as described above, in which such simulation models of the simulation are executed on a virtual machine of the real processor which are compiled for the processor type of the real processor but not for the operating system of the real processor, and such simulation models of the simulation are executed on the real processor without emulation which are compiled for the processor type of the real processor and for the operating system of the real processor, it is preferably provided that the execution of a simulation model compiled for a particular processor type on an emulated processor of the corresponding processor type is achieved in that a simulation run with an emulation present on the processor is started for one of the available processor types and, if this simulation run may not be completed successfully, a switch is made to a simulation run with an emulation for a different processor type until a simulation run has been completed successfully.

In other words, the binaries in the emulator may be started on different processor models in this way, so that the processor types may be ascertained with the aid of error-free simulation runs. The invention finally specifies that all models are initially carried out with an emulator. All target systems for which a processor model is present may be simulated thereby. It may be easily determined in this way whether the processor model is actually present. The user of the method therefore does not have to perform configuration activities. While the processor model is implicitly predefined by the simulator in conventional methods, it is now possible to easily and reliably ascertain an existing compatibility, in particular if the latter is not explicitly specified or available.

It is furthermore provided according to an example of the invention that the simulation ascertains which simulation model is required most of the time for execution, and it ascertains the processor type for which this simulation model is compiled. In this connection, a switch to the ascertained processor type is preferably subsequently made automatically for the further method.

The best hardware in relation to the models may be suggested in this way. The models may also contain unknown binaries, as described above. Due to the simulation, the simulator may determine which model represents the bottleneck in the calculation and whether an emulation is being carried out for this model and thus a faster execution would be possible without an emulation of this type.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWING

The present invention will become more fully understood from the detailed description given hereinbelow and the accompanying drawings which are given by way of illustration only, and thus, are not limitive of the present invention, and wherein the FIGURE schematically shows a method according to an example of the invention.

### DETAILED DESCRIPTION

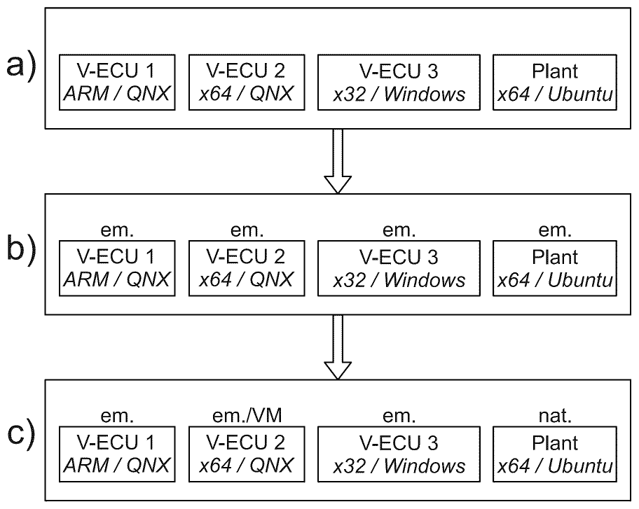

According to the example of the invention illustrated in the FIGURE, an overall system is provided, which includes four different simulation models. The submodels of the overall system are compiled for different processor types. This is illustrated schematically under a) in the FIGURE: Three V-ECU models are provided, designated as V-ECU 1, V-ECU 2, and V-ECU 3 in FIG. 1, which are compiled for ARM/QNX (processor model: ARM/operating system: QNX), x64/QNX (processor model: x64/operating system: QNX), and x86/Windows (processor model: x86/operating system: Windows), respectively. A plant model is additionally provided, which is compiled for x64/Ubuntu (processor model: x64/operating system: Ubuntu).

It is shown under b) in the FIG. 1 that the simulation system runs on a simulator within an x64/Ubuntu system, all four models also being operated under an emulation of their particular processor model in the first simulation run, as indicated by the abbreviation “em.” for all four models. This is the implementation of the feature essential to the invention that the invention always carries out an emulation of the corresponding processor type on the real processor, at least initially, regardless of the processor type for which a simulation model is compiled, even if the emulated processor type matches the processor type of the real processor.

In principle, all models except for the model compiled for x64/Ubuntu must run in an emulation, since the simulation system runs on a simulator within an x64/Ubuntu system. The x64/Ubuntu model could thus run more efficiently directly, i.e., without an emulation. To facilitate this after the startup of the method, i.e., after the first simulation run, the procedure in the present case is that a simulation run is started with an emulation present on the processor for one of the available processor types and, if this simulation run may not be completed successfully, a switch is made to a simulation run with an emulation for another processor type until a simulation run has been completed successfully; in the present case, therefore, it has been ascertained that the plant model for 64/Ubuntu has been compiled. In the present case, the plant model may thus run directly (naturally) on the real processor without emulation, which is indicated by “nat.” in the FIGURE.

The V-ECU 2 model is a special case: It is compiled for the processor type of the real processor but not for the operating system of the real processor. In this situation, a more efficient operation may be achieved in any case, in that this model runs under an emulation on a virtual machine (VM) of the real processor, indicated by “em./VM” in this case.

According to an example of the invention, it is also possible for the simulator to suggest an optimal hardware with respect to the models. The models may also contain unknown binaries, as described farther above. Due to the simulation, the simulator may determine which model represents the bottleneck in the calculation and whether or not this model is now emulated and thus could possibly be executed faster.

This is the case, for example, if the simulator recognizes a simulation system made up of 3 models for an ARM processor, 4 freely compilable models, and 5 models for an x64 processor. If, as described above, it is now determined that the models compiled for the ARM processor represent the computational bottleneck, but the simulation takes place on an x64 system, an output may take place automatically, so that the use of an ARM hardware in the cloud would be more efficient that the x64 hardware currently being used.

An essential advantage of the invention is therefore that a hardware-independent simulation is made possible by the processor emulation of the models, which always takes place initially and thus as standard procedure, while hardware and operating system requirements may be used without further configurations on the simulation model. Since a user of the invention does not need to decide at the outset whether a high flexibility or a high efficiency is needed, different interests of the user may be served simultaneously.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for carrying out a simulation on a real processor of a first processor type, the method comprising:
providing the simulation with at least one simulation model that is compiled for the first processor type; and
executing the simulation model compiled for the first processor type on the real processor of the first processor type as an emulation of the processor of the first processor type.

2. The method according to claim 1, wherein the simulation includes at least one simulation model, which is compiled for a second processor type, which is different from the first processor type, the method further comprising:
running the simulation model compiled for the second processor type on the real processor of the first processor type as an emulation of the processor of the second processor type.

3. The method according to claim 1, wherein, after executing the simulation model compiled for the first processor type on the real processor of the first processor type as an emulation of the processor of the first processor type, the following steps are carried out:
executing those simulation models of the simulation on a virtual machine of the real processor which are compiled for the processor type of the real processor but not for the operating system of the real processor; and
executing those simulation models of the simulation on the real processor without emulation which are compiled for the processor type of the real processor and for the operating system of the real processor.

4. The method according to claim 1, wherein the execution of a simulation model compiled for a particular process type on an emulated processor of the corresponding processor type is achieved in that a simulation run using an emulation present on the processor is started for one of the available processor types and, if this simulation run is not completed successfully, a switch is made to a simulation run having an emulation for another processor type until a simulation run has been completely successfully.

5. The method according to claim 1, wherein the simulation ascertains which simulation model is required most of the time for execution, and it ascertains the processor type for which this simulation model is compiled.

6. The method according to claim 5, wherein a switch to the ascertained processor type is subsequently made automatically for the further method.
